(19) United States
(12) Patent Application Publication
(10) Pub. No.: US 2018/0216225 A1
(43) Pub. Date: Aug. 2, 2018

(54) EXFOLIATION PROCESS FOR REMOVAL OF DEPOSITED MATERIALS FROM MASKS CARRIERS, AND DEPOSITION TOOL COMPONENTS

(71) Applicant: APPLIED MATERIALS, INC., Santa Clara, CA (US)

(72) Inventors: Daoying SONG, San Jose, CA (US); Byung Sung Leo KWAK, Portland, OR (US)

(21) Appl. No.: 15/505,570

(22) PCT Filed: Aug. 28, 2015
(86) PCT No.: PCT/US15/47403

§ 371 Date: Feb. 21, 2017

Related U.S. Application Data
(60) Provisional application No. 62/042,922, filed on Aug. 28, 2014.

(51) Int. Cl. C23C 16/44; B08B 3/12; B08B 3/04; C23C 14/56

(52) U.S. Cl. CPC C23C 16/4407; B08B 3/12; C23C 16/4404; C23C 14/564; C23C 16/4412; B08B 3/045

(57) ABSTRACT

A method for exfoliation of deposited material off a work piece may comprise: immersing the work piece in an ultrasonic bath and applying ultrasonic energy, wherein the ultrasonic bath contains a fluid either held at a constant temperature within the range from greater than room temperature to less than the fluid boiling point, or the fluid is cycled over a ΔT chosen within the range between room temperature and less than the fluid boiling point, wherein the temperature is chosen to provide a significant CTE mismatch between the layer and the work piece in order to promote exfoliation of the layer off the work piece, and wherein process time in the ultrasonic bath is within a range from several seconds up to 120 minutes for loosening the layer; cleaning the work piece by rinsing with liquids; and drying the work piece. A system is described for running the exfoliation process.

### CROSS-REFERENCE TO RELATED APPLICATIONS

This application claims the benefit of U.S. Provisional Application No. 62/042,922, filed Aug. 28, 2014.

### FIELD

Embodiments of the present disclosure relate generally to processes and systems for exfoliation of deposited layers of material off work pieces such as masks, carriers, and other deposition system components, and more specifically, although not exclusively, to processes and systems for exfoliation of deposited layers off the surfaces of work pieces comprising application of ultrasonic energy to the pieces in a temperature controlled liquid, the temperature being controlled to increase stress at the interface between the deposited layers and the work piece due to a CTE (coefficient of thermal expansion) mismatch between the materials of the deposited layer(s) and the work piece.

### BACKGROUND

Deposition systems for depositing thin films of materials on a substrate are widely used in many industries, such as the semiconductor industry, thin film battery industry, electrochromics industry, flat panel display industry, etc. These deposition systems may utilize a variety of work pieces such as masks, substrate carriers and sub-carriers, other deposition system components, etc. These work pieces need to be cleaned on a frequent basis to remove deposited material that has built up on the surfaces of the work pieces. The deposited materials may include a wide range of materials such as metals, semiconductors, insulators, electrolytes, etc. Generally, aggressive chemical processes (often using hazardous or toxic chemicals) or mechanical processes (that may negatively affect the dimensions and integrity of the work pieces) are used to clean these work pieces.

Clearly, there is a need for less aggressive processes for cleaning work pieces that do not use hazardous or toxic chemicals and do not significantly affect the dimensions or integrity of the work pieces.

### SUMMARY

Methods and equipment for removing deposited layers from deposition system work pieces, such as shadow masks, carriers, sub-carriers, other deposition system components, etc. are described herein. Work pieces from a wide variety of deposition systems, including PVD (physical vapor deposition), CVD (chemical vapor deposition), PECVD (plasma enhanced physical vapor deposition), sputtering, HWCVD (hot wire chemical vapor deposition), ALD (atomic layer deposition) systems, etc., may benefit from the processes described herein. It is envisaged that a very wide range of deposited materials, including metals, semiconductors, insulators, electrolytes, etc. may be removed using embodiments of the disclosed methods. Embodiments of the processes described herein may include applying ultrasonic energy to the coated work pieces in a temperature controlled liquid for removal of the built up deposited material. These processes are based on inducing interfacial stress due to CTE mismatch between the deposited layer(s) and the work piece to promote exfoliation of the deposited material during exposure to ultrasonic energy. As such, a temperature, or range of temperatures, within the operating range of the exfoliation equipment may be determined for assisting in developing bond breaking levels of interfacial stress and thus better exfoliation/delamination of the deposited layer(s)—leaving very clean, dimension-unaffected work pieces for reuse.

According to some embodiments, a process for exfoliation of deposited material off one or more work pieces such as masks, carriers, and other material deposition system components, may comprise: providing a work piece with a layer of deposited material coating the surface of the work piece; immersing the work piece in an ultrasonic bath and applying ultrasonic energy to the work piece, wherein the ultrasonic bath contains a fluid and the fluid is held at a constant temperature within the range from greater than room temperature to less than the fluid boiling point, wherein the constant temperature is chosen to provide a significant CTE (coefficient of thermal expansion) mismatch between the layer of deposited material and the work piece in order to promote exfoliation of the layer of deposited material off the work piece, and wherein process time in the ultrasonic bath is within a range from several seconds up to 120 minutes for loosening the layer of deposited material; cleaning the work piece by rinsing with liquids; and drying the work piece.

Furthermore, according to some embodiments, a process for exfoliation of deposited material off one or more work pieces such as masks, carriers, and other material deposition system components, may comprise: providing a work piece with a layer of deposited material coating the surface of the work piece; immersing the work piece in an ultrasonic bath and applying ultrasonic energy to the work piece, wherein the ultrasonic bath contains a fluid and the water is cycled over a ΔT chosen within the range between room temperature and less than the fluid boiling point, wherein the work piece is subject to a multiplicity of cycles over ΔT during immersion in the ultrasonic bath, wherein the ΔT is chosen to provide excursions through temperatures at which there is a significant CTE (coefficient of thermal expansion) mismatch between the layer of deposited material and the work piece in order to promote exfoliation of the layer of deposited material off the work piece, and wherein process time in the ultrasonic bath is within a range from several seconds up to 120 minutes for loosening the layer of deposited material; cleaning the work piece by rinsing with liquids; and drying the work piece.

Furthermore, this disclosure describes apparatus and systems configured for carrying out the aforementioned processes. According to some embodiments, a system for exfoliation of deposited material off one or more work pieces such as masks, carriers, and other material deposition system components, may comprise: a first apparatus for automated mechanical abrading of a work piece coated with a layer of deposited material; a second apparatus for applying ultrasonic energy to the work piece in a temperature controlled fluid; a third apparatus for scrubbing the layer of deposited material on the work piece with abrasive materials; a fourth apparatus for acid treatment of any residual coating on the work piece; a fifth apparatus for cleaning the work piece using liquid rinses; and a sixth apparatus for drying the work piece.

### BRIEF DESCRIPTION OF THE DRAWINGS

These and other aspects and features of the present disclosure will become apparent to those ordinarily skilled in the art upon review of the following description of specific embodiments in conjunction with the accompanying figures, wherein:

FIG. 1 is a first process flow for removal of deposited material from work pieces such as masks, carriers, and other deposition system components, according to some embodiments;

FIG. 2 is a second process flow for removal of deposited material from work pieces, according to some embodiments;

FIG. 3 is a schematic representation of an ultrasonic exfoliation apparatus, according to some embodiments; and

FIG. 4 is a representation of a system for the removal process, according to some embodiments.

### DETAILED DESCRIPTION

Embodiments of the present disclosure will now be described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Methods and equipment for removing deposited layers from deposition system work pieces, such as shadow masks, carriers, sub-carriers, other deposition system components, etc. are described herein. Work pieces from a wide variety of deposition systems, including PVD such as sputtering and evaporation, CVD such as PECVD and HWCVD, electroplating, sol-gel, ALD systems, etc., may benefit from the processes described herein. It is envisaged that a very wide range of deposited materials, including metals, semiconductors, insulators, electrolytes, organic capping layers, etc, may be removed using embodiments of the disclosed methods. The processes disclosed herein may be of benefit to a wide range of industries, including the semiconductor industry, thin film battery industry, electrochromics industry, flat panel display industry, etc. The inventors have found that the methods and equipment described herein are particularly effective for removing materials used in the TFB (thin film battery) industry—for example, LiPON and Li are readily removed from mask/subcarrier workpieces by an ultrasonic process, with the fluid in the ultrasonic bath at room temperature for Li and approximately 70° C. for UPON, as described herein, in some cases even without the need for temperature cycling of the fluid in the ultrasonic bath or mechanical processing, and LiCoO₂ is readily removed by the hot ultrasonic process in combination with mechanical processing and temperature cycling of the fluid in the ultrasonic bath over a temperature range from room temperature to just below the boiling point of the fluid.

Embodiments of the processes described herein may include applying ultrasonic energy to work pieces coated with a deposited material in a temperature controlled liquid for removal of the built up deposited material from the work pieces. These processes are based on inducing interfacial stress due to CTE mismatch between the deposited layer(s) and the work piece to promote exfoliation of the deposited material during exposure to ultrasonic energy. As such, a temperature, or range of temperatures, within the operating range of the exfoliation equipment may be determined for assisting in developing bond breaking levels of interfacial stress and thus better exfoliation/delamination of the deposited layer(s)—leaving very clean, dimension-unaffected work pieces for reuse.

Work pieces may be made of materials such as: ferromagnetic materials like Invar (an Fe—Ni alloy with a very low CTE, which is commonly used as a mask material), other metals like stainless steel, ceramics such as Al₂O₃ and AlN, etc.

For the specific example of work pieces used in the manufacture of electrochemical devices that may benefit from the processes and equipment of the present disclosure, some typical materials that may be deposited on the work pieces and examples of the specific types of deposition systems that may be used for these depositions are provided as follows. An example of a cathode layer is a LiCoO₂ layer, of an anode layer is a Li metal layer, and of an electrolyte layer is a LiPON layer. However, it is expected that a wide range of cathode materials such as LiMn₂O₄ and LiNiCoAlO₂, V₂O₅, LiMnO₂, Li₅FeO₄, NMC (NiMnCo oxide), NCA (NiCoAl oxide), LMO (LiₓMnO₂), LFP (LiₓFePO₄), LiMn spinel, etc. may be used, a wide range of anode materials such as Si, C, silicon-lithium alloys, lithium silicon sulfide, Al, Sn, etc. may be used, and a wide range of lithium-conducting electrolyte materials such as solid polymer electrolytes, LiI/Al₂O₃ mixtures, LLZO (LiLaZr oxide), LiSiCON, etc. may be used. Various electrically conducting materials may also be deposited, for example as anode or cathode current collector layers, including one or more of Ag, Al, Au, Ca, Cu, Co, Sn, Pd, Zn and Pt which may be alloyed and/or present in multiple layers of different materials and/or include Ti adhesion layers, etc. These materials may be deposited using deposition systems such as: PVD systems such as sputtering and evaporation systems, CVD systems, electroplating systems, sol-gel systems, etc. Other examples of vacuum deposition systems include PECVD, reactive sputtering, non-reactive sputtering, RF (radio frequency) sputtering, multi-frequency sputtering, electron beam evaporation, ion beam evaporation, thermal evaporation, ALD, etc. Other examples of non-vacuum based deposition include plasma spray, spray pyrolysis, slot die coating, screen printing, etc.

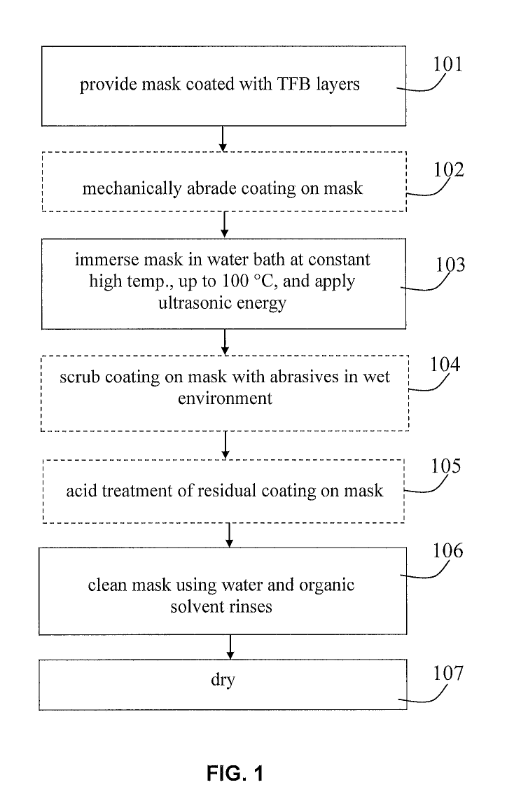

FIG. 1 provides a first example of a process flow for exfoliation of deposited material off work pieces such as masks, carriers, and other deposition system components, according to some embodiments. The process flow for the particular example of exfoliation of a material, such as LiCoO₂, off a shadow mask used for patterning electrochemical devices such as TFBs and electrochromic devices may include: providing a work piece, in this example a mask, coated with a thin film of TFB material, such as LiCoO₂ (101); if needed, mechanically abrading the coating on the mask (102)—this may be carried out in a wet environment (herein the term “wet environment” refers to either the work piece soaking in a fluid-filled container or the work piece is maintained with a film of fluid on the surface, not allowing it to dry) to reduce the generation of airborne particulates, and steel wool, sand paper, etc. may be used for the abrading; immersing the mask in an ultrasonic bath and applying ultrasonic energy to the mask (103), wherein the bath contains a fluid (such as water) and is held at a constant temperature within the range from greater than room temperature to less than the fluid boiling point (100° C. for water), and in embodiments in the range from 60° C. to 80° C., wherein the temperature is chosen to provide a CTE mismatch between the layer of deposited material and the mask sufficient to promote exfoliation of the deposited material off the mask, and wherein the process time in the ultrasonic bath may be varied from several seconds up to 120 minutes if needed to loosen the deposited material; after the ultrasonic treatment, if needed, scrubbing the mask with an abrasive material—such as steel wool, sand paper, etc.—in order to remove a majority of the remaining deposited material off the surface of the mask (104)—this may be carried out in a wet environment to reduce the generation of airborne particulates; if needed, treating the mask with a dilute acid (105), such as dilute hydrochloric acid (between 5% and 25% by weight) or dilute hydrofluoric acid (less than 1% by weight), for example, in order to assist in removing any remaining deposited material on the surface of the mask—the specific acid treatment will depend on the mask material and the treatment may be designed to avoid affecting the integrity and dimensions of the mask; cleaning the mask using water (e.g. distilled water or deionized water) rinses and/or organic solvent rinses (106); and drying the mask (107)—the mask drying may be by the application of a stream of air and/or heat to the mask, for example.

Note that typically the stress between a deposited layer of a first material on a substrate of a second material will depend on the thickness of the first layer, consequently the CTE mismatch that may be sufficient to promote exfoliation in the ultrasonic bath will also depend on the thickness of the first layer—the thicker the first layer, the smaller the CTE mismatch can be in order to be able to exfoliate the first layer using methods according to embodiments as disclosed herein.

Note that one or more of the mechanically abrading (102), scrubbing (104) and acid treatment (105) may not necessarily need to be used as part of the exfoliation process, but are available to assist in the exfoliation of deposited layers off the work piece that otherwise may not easily be removed. For example, Li or LiPON layers coating masks/sub-carriers will typically exfoliate easily and completely without any additional mechanical treatment. For masks/sub-carriers coated with metals or LiCoO₂, sand paper may be used for further cleaning after ultrasonic treatment. In addition, for thick cathode TFBs, each cathode deposition typically generates more than a 10 μM thick layer of LiCoO₂ on masks/subcarriers, so cleaning of LiCoO₂ masks/sub-carriers may be necessary after each deposition to ensure good particle performance (lack of particle generation during subsequent use of the work piece). Due to the high stress in thick cathode layers, LiCoO₂ films may start to delaminate from masks/sub-carriers after the hot ultrasonic process at about 70° C., after which a light sand paper treatment is enough to remove any LiCoO₂ residuals from the masks/sub-carriers.

Furthermore, with reference to FIG. 1, the mechanical abrading may be manual or in embodiments automated, and the scrubbing may be manual or in embodiments automated. Furthermore, in embodiments, instead of immersing the work piece in an ultrasonic bath, a jet or spray of temperature controlled water provided with ultrasonic energy may be applied to the work piece, where the mask and the jet/spray may be moved relative to each other if needed for the jet/spray to reach all portions of the work piece that are covered by deposited material. Furthermore, in embodiments, ultrasonic energy may be applied to the work piece in water with additional chemicals. The additional chemicals may be chosen to bring about the combined effects of exfoliation and chemical based cleaning—for example: (1) water plus organic solvents, particularly organic solvents with a hydroxide functional group, (2) water plus an acid, or (3) water plus hydrogen peroxide. Furthermore, in embodiments one or more of the following may apply: the ultrasonic energy may be pulsed or varied otherwise, the ultrasonic frequency may be varied, and multiple ultrasonic frequencies may be used simultaneously.

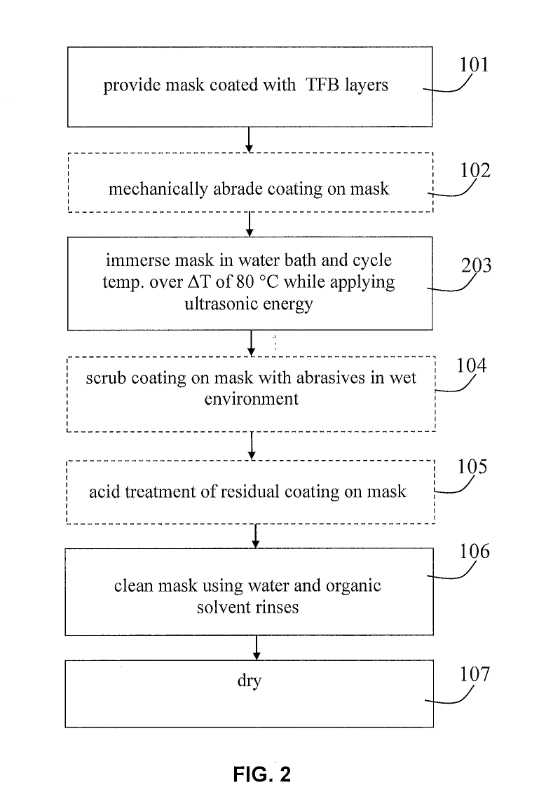

FIG. 2 provides a second example of a process flow for exfoliation of deposited material off work pieces such as masks, carriers, and other deposition system components, according to some embodiments. The second process flow for exfoliation is the same as the first process flow, but includes immersing the work piece in an ultrasonic bath and applying ultrasonic energy to the work piece, wherein the bath contains a fluid (such as water) and the temperature of the fluid is cycled over a ΔT within the range of room temperature to less than the fluid boiling point (less than 100° C. for water), wherein in embodiments ΔT may be up to 80° C., and in other embodiments ΔT is between 30° C. and 50° C., wherein the work piece is subject to a multiplicity of cycles during immersion in the ultrasonic bath, in embodiments the multiplicity may be between 2 and 5, in other embodiments the multiplicity is greater than 5, wherein the temperature is chosen to provide a CTE mismatch between the deposited material and the work piece sufficient to promote exfoliation of the deposited material from the work piece, and wherein the process time in the ultrasonic bath may be varied from several seconds up to 120 minutes if needed to loosen the deposited material (203). Note that it is proposed herein that cycling of the temperature may induce more effective removal of deposited layers in certain cases due to “movement at the interface” that will likely further enhance exfoliation of deposited layers where exfoliation has already begun; furthermore, note that cycling the temperature may increase the likelihood of passing through a temperature at which the CTE mismatch is higher—this is due to the nonlinear nature of CTE values as a function of temperature in combination with the different CTE functions for the deposited material and the work piece.

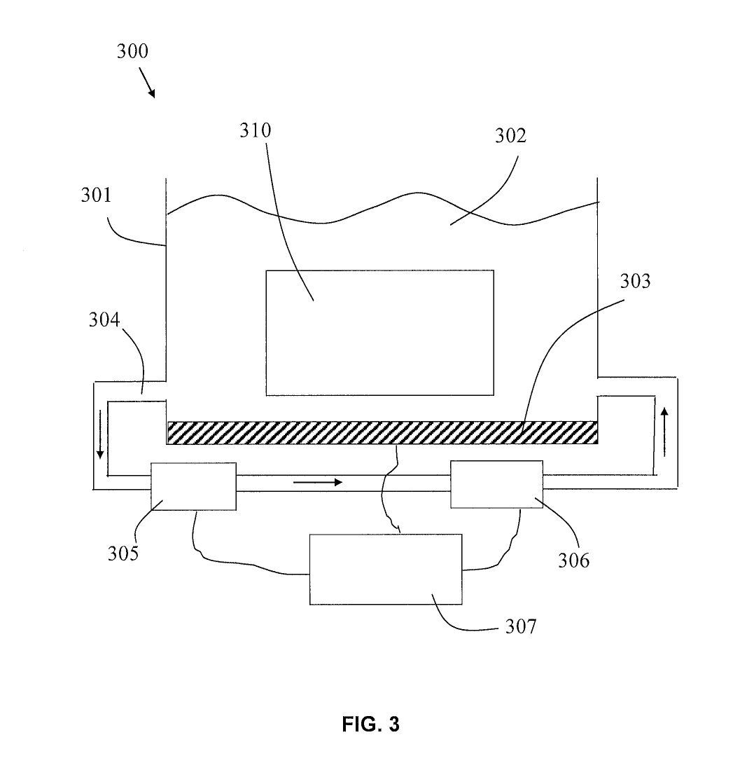

FIG. 3 shows a schematic representation of an ultrasonic exfoliation system 300, according to some embodiments. The system 300 includes a bath 301 filled with a cleaning fluid 302, such as water, in which the work piece 310 is immersed. An ultrasonic transducer 303 for providing ultrasonic energy to the fluid 302 surrounding the work piece 310 may be built into the bath, as shown, or in embodiments the transducer may be suspended in the fluid 302, or in other embodiments the transducer may be incorporated into the fluid circulation loop 304 just before the fluid reenters the bath. Fluid 302 is circulated through the bath 301 and the fluid circulation loop 304 by pump 305 and the temperature of the fluid may be increased/decreased as needed by heater/cooler 306, (Fluid temperature may also be adjusted by the addition and/or removal of fluid from the bath—for example, the addition of cold water to the bath may be used for rapid cooling.) A controller 307 is used to control fluid circulation, fluid temperature, and energy input into the fluid by the ultrasonic transducer. Furthermore, the apparatus 300 may be configured to provide rapid temperature cycling and variable ultrasonic functions (pulsing, frequency variation, etc.). For example, in embodiments rapid temperature cycling may be decreasing the bath temperature from 80° C. to room temperature in less than 2 minutes, by the addition of sufficient cold water to the bath.

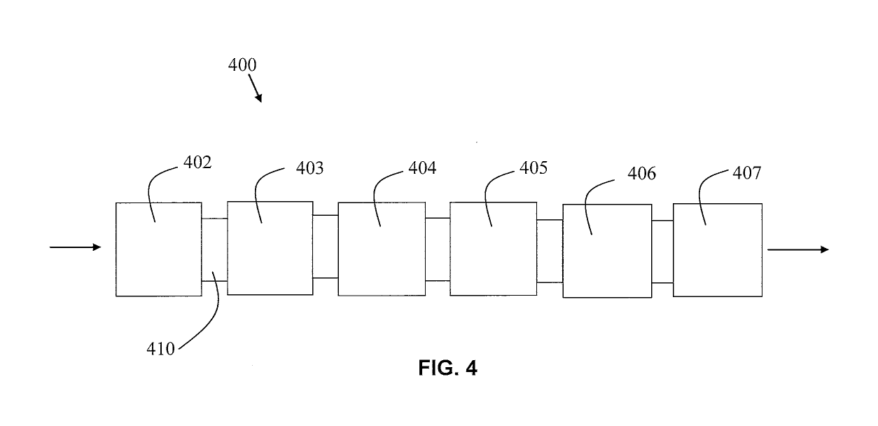

FIG. 4 shows a representation of an in-line exfoliation system 400, according to some embodiments. The system 400 may comprise; an apparatus 402 for automated mechanical abrading of a work piece; an apparatus 403 for applying ultrasonic energy to the work piece in a temperature controlled fluid—for example the ultrasonic exfoliation apparatus 300; an apparatus 404 for scrubbing the coating on the work piece with abrasive materials, in embodiments in a wet environment; an apparatus 405 for acid treatment of any residual coating on the work piece; an apparatus 406 for cleaning using water (deionized (DI) or distilled, for example) and/or organic solvent rinses; and an apparatus 407 for drying the work piece. The system 400 may have a conveyor 410, or in embodiments an overhead gantry, for moving the work piece from apparatus to apparatus. In embodiments the system 400 may be configured with more or less apparatus, as needed for the particular exfoliation processes that are to be run. Furthermore, in embodiments, the functions of several of the apparatus may be combined into one apparatus, and in further embodiments some apparatus may be stand alone.

Although embodiments of the present disclosure have been particularly described with reference to certain embodiments thereof, it should be readily apparent to those of ordinary skill in the art that changes and modifications in the form and details may be made without departing from the spirit and scope of the disclosure.

1. A method for exfoliation of deposited material off one or more work pieces such as masks, carriers, and other material deposition system components, comprising:
providing a work piece with a layer of deposited material coating the surface of said work piece;
immersing said work piece in an ultrasonic bath and applying ultrasonic energy to said work piece, wherein said ultrasonic bath contains a fluid and said fluid is held at a constant temperature within the range from greater than room temperature to less than the fluid boiling point, wherein said constant temperature is chosen to provide a significant CTE (coefficient of thermal expansion) mismatch between said layer of deposited material and said work piece in order to promote exfoliation of said layer of deposited material off said work piece, and wherein process time in said ultrasonic bath is within a range from several seconds up to 120 minutes for loosening said layer of deposited material;
cleaning said work piece by rinsing with liquids; and
drying said work piece.

2. The method of claim 1, further comprising mechanically abrading said layer of deposited material on said work piece.

3. The method of claim 1, wherein said fluid in said bath is held at a temperature in a range from 60° C. to 80° C.

4. A method for exfoliation of deposited material off one or more work pieces such as masks, carriers, and other material deposition system components, comprising:
providing a work piece with a layer of deposited material coating the surface of said work piece;
immersing said work piece in an ultrasonic bath and applying ultrasonic energy to said work piece, wherein said ultrasonic bath contains a fluid and said fluid is cycled over a ΔT chosen within the range between room temperature and less than the fluid boiling point, wherein said work piece is subject to a multiplicity of cycles over ΔT during immersion in said ultrasonic bath, wherein said ΔT is chosen to provide excursions through temperatures at which there is a significant CTE (coefficient of thermal expansion) mismatch between said layer of deposited material and said work piece in order to promote exfoliation of said layer of deposited material off said work piece, and wherein process time in said ultrasonic bath is within a range from several seconds up to 120 minutes for loosening said layer of deposited material;
cleaning said work piece by rinsing with liquids; and
drying said work piece.

5. The method of claim 4, wherein said ΔT is less than or equal to 80° C.

6. The method of claim 4, wherein ΔT is between 30° C. and 50° C.

7. The method of claim 4, further comprising mechanically abrading said layer of deposited material on said work piece.

8. The method of claim 1, further comprising, after said applying ultrasonic energy, scrubbing said work piece with an abrasive material for removing a majority of any remaining deposited material off said surface of said work piece.

9. The method of claim 1, further comprising, after said applying ultrasonic energy, treating said work piece with a dilute acid for assisting in removing any remaining deposited material on said surface of said work piece.

10. The method of claim 1, wherein said liquids comprise water.

11. The method of claim 1, wherein said liquids comprise an organic solvent.

12. A system for exfoliation of deposited material off one or more work pieces such as masks, carriers, and other material deposition system components, comprising:
a first apparatus for automated mechanical abrading of a work piece coated with a layer of deposited material;
a second apparatus for applying ultrasonic energy to said work piece in a temperature controlled fluid;
a third apparatus for scrubbing said layer of deposited material on said work piece with abrasive materials;
a fourth apparatus for acid treatment of any residual coating on said work piece;
a fifth apparatus for cleaning said work piece using liquid rinses; and
a sixth apparatus for drying said work piece.

13. The system of claim 12, wherein said system has a conveyor for moving said work piece from system to system.

14. The system of claim 12, wherein said second apparatus is configured for full immersion of said work piece in said temperature controlled fluid.

15. The system of claim 12, wherein said third apparatus is configured for scrubbing said layer of deposited material on said work piece with abrasive materials in a wet environment.

16. The method of claim 4, further comprising, after said applying ultrasonic energy, scrubbing said work piece with an abrasive material for removing a majority of any remaining deposited material off said surface of said work piece.

17. The method of claim 4, further comprising, after said applying ultrasonic energy, treating said work piece with a dilute acid for assisting in removing any remaining deposited material on said surface of said work piece.

18. The method of claim 4, wherein said liquids comprise water.

19. The method of claim 4, wherein said liquids comprise an organic solvent.
